(19) United States
(12) Patent Application Publication
(10) Pub. No.: US 2008/0257400 A1
(43) Pub. Date: Oct. 23, 2008

(54) HOLOGRAPHICALLY ENHANCED PHOTOVOLTAIC (HEPV) SOLAR MODULE

(76) Inventors: George V. Mignon, Tucson, AZ (US); Chien Wei Han, Tucson, AZ (US)

Correspondence Address: David W. Collins - Intellectual Property Law, 512 E. Whitehouse Canyon Road, Suite 100, Green Valley, AZ, 85614, US

(21) Appl. No.: 12/103,657

(22) Filed: Apr. 15, 2008

Related U.S. Application Data
(60) Provisional application No. 60/923,869, filed on Apr. 17, 2007.

(51) Int. Cl. H01L 31/052; H01L 31/0232; H01L 31/18

(52) U.S. Cl. 136/246; 136/259; 438/72; 257/E31.127

(57) ABSTRACT

A holographically enhanced photovoltaic solar module comprises: a first substrate having an outer major surface and an inner major surface, substantially parallel to each other, the first substrate being optically transparent and including a transmission grating on the inner major surface of the optically transparent substrate; a second substrate having an outer major surface and an inner major surface, substantially parallel to each other, the second substrate including a reflection grating on the inner major surface of the second substrate; and at least one solar cell interposed between the transmission grating and the reflection grating and oriented perpendicular thereto.

### CROSS-REFERENCE TO RELATED APPLICATION

The present application claims priority from provisional application 60/923,869, filed Apr. 17, 2007. Reference is made therein to Disclosure Document 575197, filed on Apr. 18, 2005.

### BACKGROUND ART

Luminescent solar concentrators are known in the art and act to trap and collect light from luminescent centers dispersed in a planar sheet. Luminescent concentrators utilize the total internal reflection in the wave-guide to trap a portion of the light emitted from the luminescent centers. The luminescent centers reradiate longer wavelength light in a 360 degree solid angle and so are inefficient in directing light to one edge of the plate or to a small region of the edge.

One example of a solar concentrator known in the art utilizes a hologram and a prism or plate; see, e.g., U.S. Pat. No. 4,863,224, issued to Afian et al. However, this solar concentrator needs to be aligned to the sun and does not provide for any passive solar tracking ability.

Also known in the art is a light gathering device comprising a hologram and a total reflection surface for a collecting monochromatic light at a single angle of incidence; see, e.g., U.S. Pat. No. 5,268,985, issued to Ando et al. However, Ando et al employ a single angle of incidence and a single wavelength, and thus require a tracking mechanism and cannot utilized the entire solar spectrum.

Yet another concentrator known in the prior art is an electromagnetic wave concentrator; see, e.g., U.S. Pat. No. 4,505,264, issued to Tremblay. The electromagnetic wave concentrator utilizes a multidielectric guiding plate to concentrate electromagnetic energy. This invention has the disadvantage of multiple reflection losses in the guiding plate and high absorption losses in some of the more cost effective embodiments. Also this invention posses difficult optical fabrication problems and hence is more expensive to fabricate.

U.S. Pat. No. 5,877,874, issued Mar. 2, 1999, and U.S. Pat. No. 6,274,860, issued Aug. 14, 2001, disclose a device for concentrating solar radiation, which employs a holographic planar concentrator (HPC) for collecting and concentrating optical radiation. The HPC comprises a planar, highly transparent plate and at least one multiplexed holographic optical film mounted on a surface thereof. The multiplexed holographic optical film has recorded therein a plurality of diffractive structures having one or more regions which are angularly and spectrally multiplexed. Two or more of the regions may be configured to provide spatial multiplexing. While the teachings of that patent are certainly useful for its intended purpose, improvements thereover are sought; the present invention represents such an improvement.

There remains a need for a solar concentrator that decreases energy losses in the concentration of solar radiation and that utilizes a substantial portion of the solar spectrum while reducing or eliminating tracking requirements.

### BRIEF DESCRIPTION OF THE DRAWINGS

FIG. 1 is a side elevational view showing a planar solar concentrator in accordance with an aspect of the invention, with incident light at normal.

FIG. 2 is a view similar to that of FIG. 1, but depicting a source of light loss.

FIG. 3 is a view similar to that of FIG. 2, but including two reflection holograms in accordance with an aspect of the invention to reduce light loss.

FIG. 4 is a view similar to that of FIG. 3, but including two reflection holograms, with the back of one reflection hologram silvered in accordance with an aspect of the invention.

FIG. 5 is a side elevational view showing a planar solar concentrator in accordance with another aspect of the invention, including cylindrical lenses in association with solar cells.

FIG. 6 is a view similar to that of FIG. 1, depicting the bandwidth of light diffracted by a transmission grating.

FIG. 7 is a view similar to that of FIG. 6, but depicting the bandwidth of light diffracted by a reflection grating.

FIG. 8 is a view similar to that of FIG. 1, depicting high Fresnel reflection resulting from light that is diffracted at steep angles.

FIG. 9 is a view similar to that of FIG. 1, but with incident light at non-normal.

FIG. 10 is a view similar to that of FIG. 9, but with incident light at an extreme offset angle.

FIGS. 11-13 depict the recording (FIG. 11) and playback (FIGS. 12-13) of volume transmission holograms.

FIGS. 14-18 depict the steps of constructing a hologram in a substrate.

### DETAILED DESCRIPTION

A. Examples of Planar Solar Concentrators

In this invention, we disclose a planar solar concentrator that is light weight, high efficiency, and low cost. FIG. 1 depicts one embodiment of the planar solar concentrator 10 of the invention. It uses a transmission grating 12 on the top side (the side closer to the sun) and a first reflection grating 14 on the bottom, or opposite, side to concentrate sunlight 16 onto mono-facial or bifacial solar cells 18, as shown in FIG. 1. There is a rigid structure (not shown) to support the gratings and the solar cells.

The holographically enhanced photovoltaic solar module comprises: a first substrate having an outer major surface and an inner major surface, substantially parallel to each other. The first substrate is optically transparent and includes a transmission grating on the inner major surface of the optically transparent substrate. The solar module further includes a second substrate having an outer major surface and an inner major surface, substantially parallel to each other. The second substrate including a reflection grating on the inner major surface of the second substrate. At least one solar cell is interposed between the transmission grating and the reflection grating and oriented perpendicular thereto.

In some embodiments, the two substrates are parallel to each other, 0 degrees. In other embodiments, the two substrates are non-parallel to each other, by as much as 15 degrees. By “substantially parallel” is meant that the two substrates are in the range of 0 to 15 degrees.

In some embodiments, both the transmission grating 12 and the first reflection grating 14 are created in holographic films, which are thinner and lighter than the gratings themselves would be. Accordingly, the phrases “grating” and “hologram” are often used interchangeably herein.

The gratings employed herein (transmission and reflection) may comprise a film of a holographic material supported on a substrate that is configured to act as a grating; the formation of such gratings is described below. Alternatively, the gratings may comprise a grating or hologram that is formed in the surface of the substrate itself.

The grating holograms can be made in different types of media such as dichromated gelatin (DCG), silver halide, sol gel, photopolymer or embossed onto a plastic. The reflection hologram may also have an optional silvered reflector behind it.

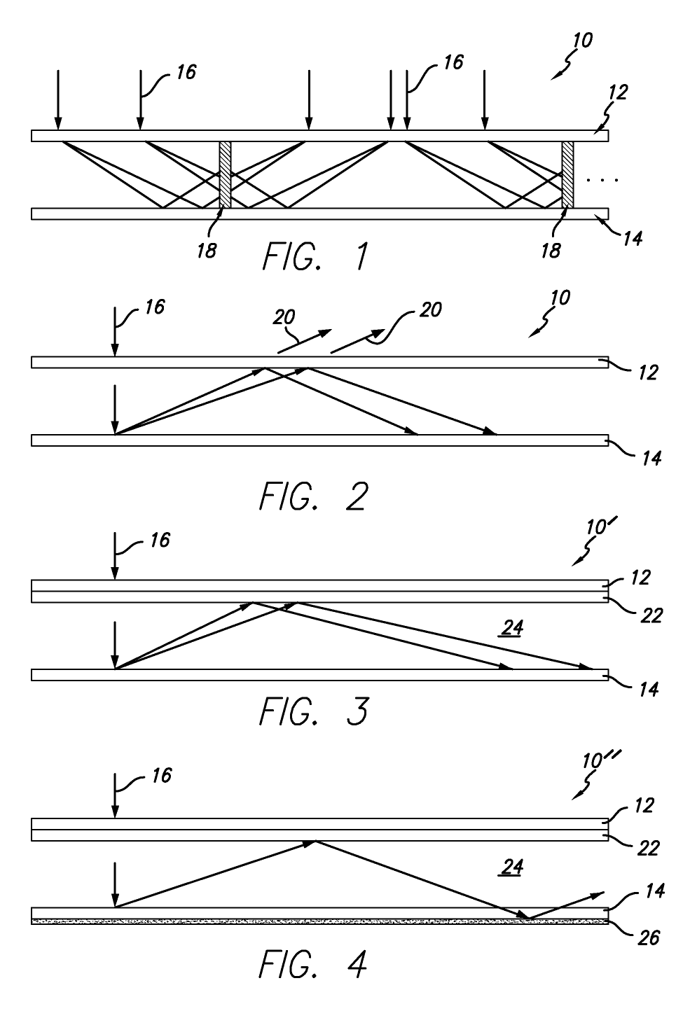

For the light diffracted at less steep angles, its Fresnel reflection is lower and light may exit the transmission hologram, as shown in FIG. 2, denoted at 20.

To prevent light from exiting the transmission hologram, we can add a second reflection hologram 22 to the structure 10′, next to the transmission hologram 12, to redirect the light back into cavity 24. The second reflection hologram 22 will redirect the light back into the cavity 24 at a steeper angle. The addition of the reflection hologram 22 is shown in FIG. 3.

We can also place a silvered mirror 26 behind the first reflection hologram 14 to further prevent light from exiting the first reflection hologram. The addition of the silvered mirror 26 to form structure 10″ is shown in FIG. 4.

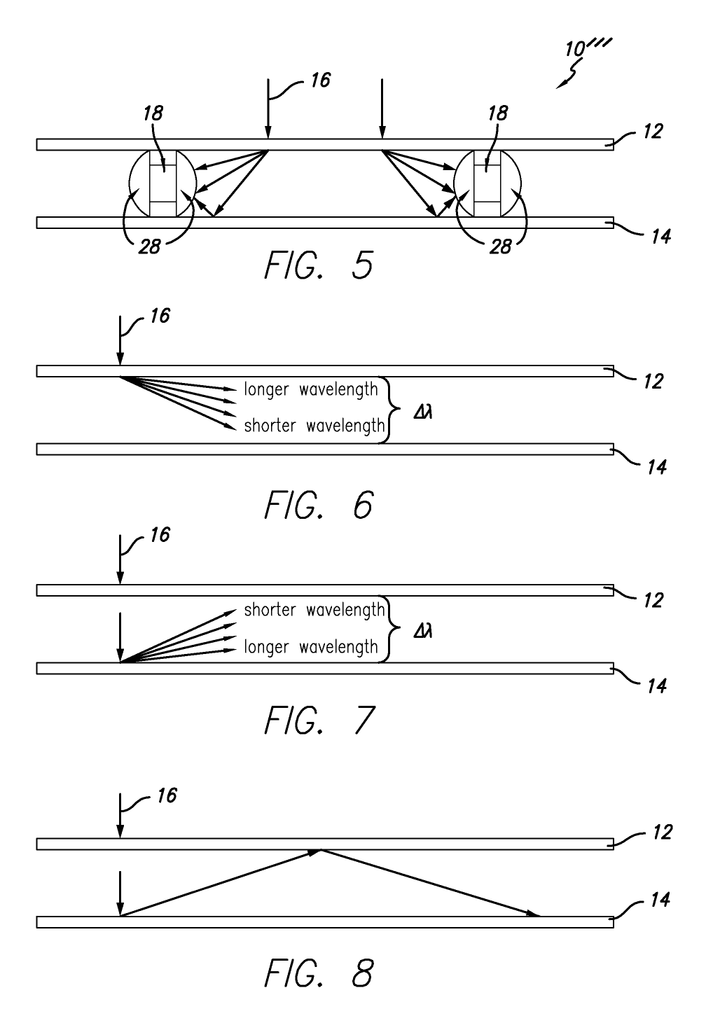

A cylindrical lens 28 can be placed in conjunction with the solar cells 18, on one or both sides of each solar cell 18 to further concentrate the light 16 onto the solar cells in structure 10′″, shown in FIG. 5.

B. Considerations Regarding Sunlight at Normal Incidence

Sunlight 16 incident on the transmission grating 12 will be dispersed to different angles for different colors. The red light (longer wavelengths) will be diffracted at a larger angle with respect to the surface normal and the violet light (shorter wavelengths) will be diffracted at a smaller angle. The exact angles can be calculated by the grating equation, given below in Eqn. 1.

More specifically, when light enters the transmission hologram 12 at normal incidence, there is only a bandwidth of light Δλ which will be diffracted. The steeper the diffracted light angle, the smaller the bandwidth. Only those wavelengths that satisfy the grating equation will be diffracted. The result is depicted in FIG. 6. In this case, the diffraction of light 16 occurs from the transmission hologram 12.

For those portions of incident light 16 that are not diffracted by the transmission hologram 12, they pass straight through the transmission hologram onto the reflection hologram 14. FIG. 7, which is similar to FIG. 6, shows diffraction of light from the reflection hologram 18. The spectrum of light is seen to be inverted from the situation in FIG. 6.

The reflection hologram is made such that it diffracts light in the direction of the solar cells 18 (not shown in FIGS. 6 and 7, but shown in FIG. 1, for example). The reflection hologram 14 has the same property as the transmission hologram 12 in that the steeper the light is diffracted, the smaller the bandwidth. Light that is diffracted at steep angles will experience high Fresnel reflection when it reaches the transmission hologram 12, as depicted in FIG. 8.

A bifacial solar cell 18, discussed in greater detail below, may be placed vertically between the grating films 12, 14; see, FIG. 1. Sunlight 16 that falls upon the region of the transmission grating 12 that is closer to the bifacial cell 18 will directly be diffracted onto the solar cell. Sunlight 16 that falls further away from the bifacial cell 18 will be diffracted onto the bottom hologram (reflection hologram 14). The hologram 14 on the bottom is a reflection grating and will diffract the light that falls on it onto the bifacial solar cell 18. We design the grating 14 such that the light will reach the solar cell 18 with a single bounce. In other embodiments, multiple bounces of the light may be employed.

The distance between the upper grating 12 and the lower grating 14 is within a range of about 3 to 200 mm, and a typical distance is about 0.5 inch (12.7 mm). The distance between the bifacial cells 18 will be calculated and computer simulated using the rigorous coupled-wave method to determine the best possible efficiency. As an example, with a solar module 10. 10′, 10″, 10′″ including a plurality of solar cells 18, the separation distance, center-to-center, may be within a range of about 12 to 800 mm.

C. Considerations of Sunlight at Non-Normal Incidence

When the sunlight 16 is not at normal incidence, then the diffraction angle for different colors will change. According to the grating equation, all the diffracted angles to the left of the bifacial cell 18 will shift in the direction of the incident light. The incident sunlight can now illuminate an area of the transmission grating that is further away from the bifacial cell and still diffract directly onto the cell.

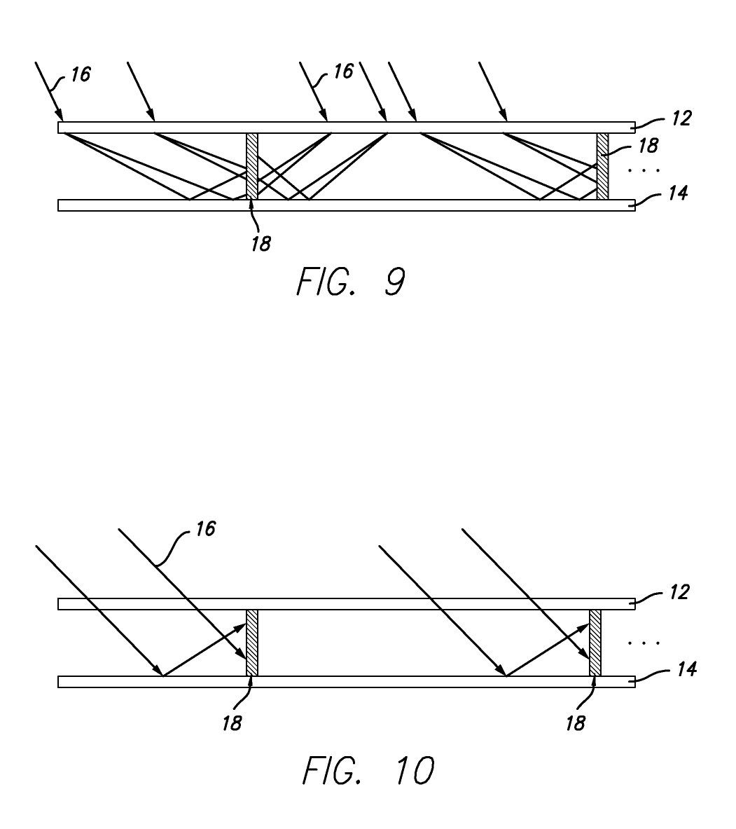

The opposite effect occurs on the right side of the bifacial cell 18. For the light to directly diffract onto the cell 18, the incident sunlight 16 now have to illuminate an area of the transmission grating 12 that is closer to the bifacial cell because the diffracted angles are not as large with respect to the surface normal. This is illustrated in FIG. 9.

The grating equation determines the exact amount of angle change for different colors. The amount of light diffracted will also change as a result. If the diffraction gratings are optimized at normal incidence, then the diffraction efficiency will be lowered when the incident light is at non-normal incidence.

D. Considerations of Sunlight at Extreme Offset Angles

When the sunlight is incident on the holograms at extreme offset angles, the transmission grating 12 will not be on Bragg and will not diffract the sunlight. If the sunlight is at a steep enough angle and is close enough to the bifacial cell, then light will directly fall upon it.

FIG. 10, which is a view similar to that of FIG. 1, shows the resulting capture of light by the solar cells 18 where the incident light 16 is at such an extreme offset angle, rather than normal (as shown in FIG. 1).

If the sunlight is further away, then it will fall on the grating with silvered backing. The grating will not be on Bragg and will not disperse the incoming light into different colors. However, since it has a silvered backing, the light will be reflected at the same angle as the incident angle onto the bifacial cell.

E. Construction of Holograms

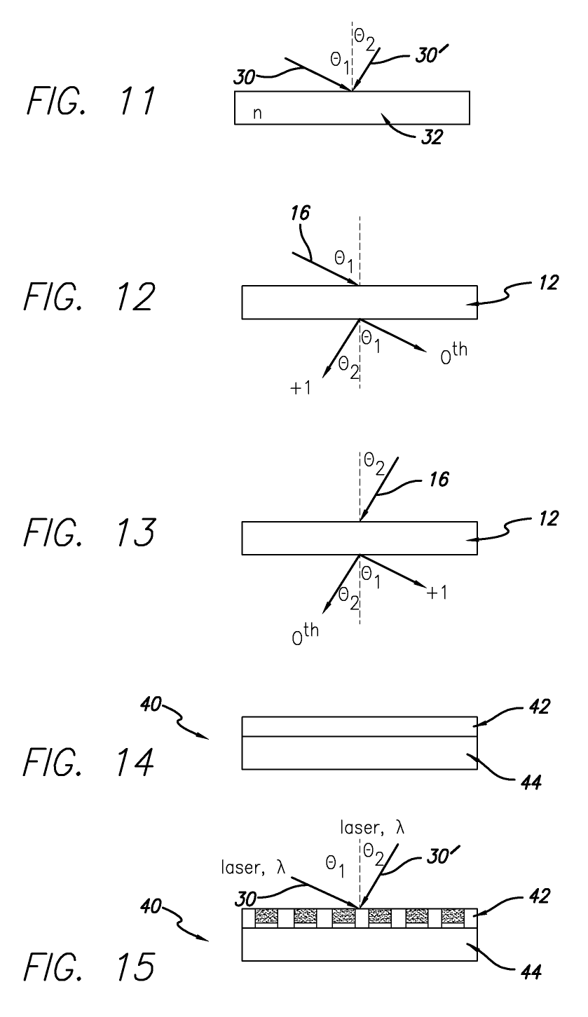

A volume transmission hologram 12 is made by interfering two laser beams 30, 30′ at two different angles θ₁ and θ₂ on the same side of a photosensitive recording medium 32 in air, as depicted in FIG. 11. The laser has a wavelength of λ.

After the laser beams 30, 30′ enter the photosensitive medium 32, they are refracted according to Snell's law. The interference of the two laser beams in the medium creates fringes and can be described by the grating equation,

n sin θ₁+n sin θ₂=mζ/Λₓ, Eqn. 1

where n is the index of refraction of the medium, θ₁ and θ₂ are the recording angles, m is the diffracted order number, λ is the recording wavelength, and Λₓ is the x-component of the grating period. The fringe slant is determined by the bisector of the angle between θ₁ and θ₂. The grating equation predicts the angle of diffraction as a function of grating period, the wavelength, and the incident angle.

The grating equation does not predict the amount of light diffracted. A numerical method called the rigorous coupled wave method is used to predict the amount of light diffracted. The recording medium 32 can be of a volume type material such as photopolymer, silver halide, or dichromated gelatin. If the medium 32 is silver halide or dichromated gelatin, then it needs to be chemical processed after exposure. The region of the film that receives higher exposure has a higher index of refraction, and the region which receives lower exposure has a lower index of refraction.

During playback of the hologram 12, if light 16 is incident upon the hologram at angle θ₁, then the light diffracted will be at the other recording angle θ₂. This situation is depicted in FIG. 12.

The angle θ₂ is defined to be +1 order and the light transmitted straight through is the 0^{th} order. If the light incident upon the hologram at angle θ₂, then the light diffracted is θ₁. This situation is depicted in FIG. 13.

A surface relief grating 40 is made by using a photoresist material 42, or other photosensitive material, deposited on a substrate 44, such as a metal, glass, or any material that can support variation in thickness. The structure is depicted in FIG. 14.

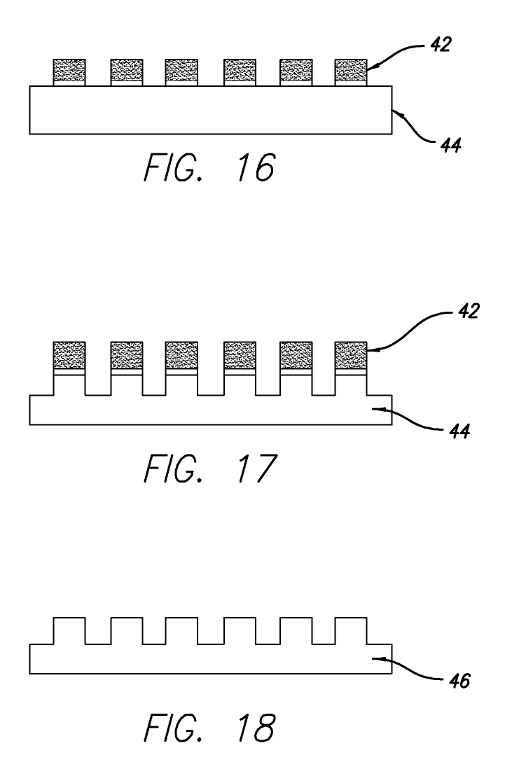

There are different types of photoresists that are sensitive to different wavelengths. One would expose the photoresist interferometrically with two laser beams like exposing a volume hologram interferometrically, as discussed above with reference to FIG. 11. The resulting structure is shown in FIG. 15.

After exposure, the structure 40 is immersed in an etchant to remove the unexposed part of the photoresist 42 so that portions of the substrate 44 are exposed. The resulting structure is shown in FIG. 16.

Then the structure 40 is placed in a chemical etchant to remove portions of the exposed substrate 44 to a certain depth, as depicted in FIG. 17.

Finally, the photoresist 42 is removed by another etchant and a surface relief grating 46 is formed, as shown in FIG. 18. The surface relief grating can be used as a master to copy many gratings onto a metal foil or other compressible material. In this manner, transmission gratings 12 may be formed in optically transparent substrates and reflection gratings 14 may be formed in substrates.

Examples of holographic recording to form gratings are shown, for example, in U.S. Pat. Nos. 5,877,874 and 6,274,860, the contents of which are hereby incorporated by reference herein.

The holographically enhanced photovoltaic solar module disclosed herein may find a variety of uses, including, without limitation, in buildings as windows and skylights.

We claim:

1. A holographically enhanced photovoltaic solar module, comprising:
a first substrate having an outer major surface and an inner major surface, substantially parallel to each other, said first substrate being optically transparent and including a transmission grating hologram on said inner major surface of said optically transparent substrate;
a second substrate having an outer major surface and an inner major surface, substantially parallel to each other, said second substrate including a reflection grating hologram on said inner major surface of said second substrate; and
at least one solar cell interposed between said transmission grating hologram and said reflection grating hologram and oriented perpendicular thereto.

2. The solar module of claim 1 wherein said at least one solar cell is monofacial.

3. The solar module of claim 2 wherein a cylindrical lens is associated with said monofacial side of said solar cell.

4. The solar module of claim 1 wherein said at least one solar cell is bifacial.

5. The solar module of claim 4 wherein a cylindrical lens is associate with at least one side of said solar cell.

6. The solar module of claim 1 wherein said inner surface of said first substrate and said inner surface of said second substrate are separated by a distance within a range of about 3 to 200 mm.

7. The solar module of claim 1 including a plurality of solar cells with a separation distance, center-to-center, within a range of about 12 to 800 mm.

8. The solar module of claim 1 further comprising a silvered reflector surface behind said reflection grating hologram.

9. The solar module of claim 1, oriented so that solar radiation is incident on said outer surface of said first substrate.

10. The solar module of claim 1 further comprising a reflection grating hologram formed on said transmission grating hologram.

11. The solar module of claim 1 wherein said transmission grating hologram is supported on said inner major surface of said optically transparent substrate.

12. The solar module of claim 1 wherein said transmission grating hologram is formed on said inner major surface of said optically transparent substrate.

13. The solar module of claim 1 wherein said reflection grating hologram is supported on said inner major surface of said second substrate.

14. The solar module of claim 1 wherein said reflection grating hologram is formed on said inner major surface of said second substrate.

15. A method of fabricating a holographically enhanced photovoltaic solar module, said method comprising:
providing a first substrate having an outer major surface and an inner major surface, substantially parallel to each other, said first substrate being optically transparent and including a transmission grating hologram on said inner major surface of said optically transparent substrate;
providing a second substrate having an outer major surface and an inner major surface, substantially parallel to each other, said second substrate including a reflection grating hologram on said inner major surface of said second substrate; and
interposing at least one solar cell between said transmission grating hologram and said reflection grating hologram and oriented perpendicular thereto.

16. The method of claim 15 wherein said transmission grating hologram is prepared by interfering two laser beams at two different angles on the same side of a photosensitive recording medium.

17. The method of claim 15 wherein said reflection grating hologram is pre-pared by interfering two laser beams at two different angles on the same side of a photosensitive recording medium.

18. A method of directing solar radiation to at least one solar cell, said method comprising:
providing a holographically enhanced photovoltaic solar module, comprising:
a first substrate having an outer major surface and an inner major surface, substantially parallel to each other, said first substrate being optically transparent and including a transmission grating hologram on said inner major surface of said optically transparent substrate,
a second substrate having an outer major surface and an inner major surface, substantially parallel to each other, said second substrate including a reflection grating hologram on said inner major surface of said second substrate, and
said at least one solar cell interposed between said transmission grating hologram and said reflection grating hologram and oriented perpendicular thereto; and
introducing said solar radiation onto said outer major surface of said first substrate.
